(19) United States
(12) Patent Application Publication
(10) Pub. No.: US 2004/0122544 A1
(43) Pub. Date: Jun. 24, 2004

(54) Delta-sigma modulator, method of switching delta-sigma modulator, and digital amplifier

(75) Inventor: Mitsuya Komamura, Saitama (JP)

Correspondence Address: MORGAN LEWIS & BOCKIUS LLP, 1111 PENNSYLVANIA AVENUE NW, WASHINGTON, DC, 20004, US

(73) Assignee: Pioneer Corporation

(21) Appl. No.: 10/716,508

(22) Filed: Nov. 20, 2003

(30) Foreign Application Priority Data
Nov. 25, 2002 (JP) P. 2002-340745

(51) Int. Cl. G06F 17/00; H03G 3/00

(52) U.S. Cl. 700/94; 381/104

(57) ABSTRACT

A delta-sigma modulator includes a quantization bit rate detection unit that detects a quantization bit rate of a digital audio signal, a volume setting value detection unit that detects a volume setting value of the digital audio signal; a filter that includes plural sets of filter coefficients having different shaping properties and allows the quantization noise to pass, and a filter coefficient switcher that switches the filter coefficients of the filter in accordance with the detection results of the quantization bit rate detection unit and the volume setting value detection unit. The delta-sigma modulator detects the quantization bit rate of an input signal and switches the filter coefficients to the low-order filter coefficient set when a source has a low quantization bit rate.

The present disclosure relates to the subject matter contained in Japanese Patent Application No.2002-340745 filed Nov. 25, 2002, which is incorporated herein by reference in its entirety.

### BACKGROUND OF THE INVENTION

1. Field of the Invention

The present invention relates to a delta-sigma modulator, a method of switching a delta-sigma modulator, and a digital amplifier.

2. Description of the Related Art

Conventionally, a digital amplifier using delta-sigma modulation shifts quantization noise to a high-frequency band by noise shaping, to thereby secure the S/N ratio of an audio band.

FIG. 1 is a block diagram showing the configuration of a conventional quintic delta-sigma modulator. Noise shaping filter coefficients (a1, a2, a3, a4, a5) are fixed. In this manner, the coefficients of the conventional delta-sigma modulator serving as a noise shaping filter used in a digital amplifier are fixed (e.g., see J. M. Goldberg and A. B. Sandler, “Noise Shaping and Pulse-Width Modulation for an All-Digital Audio Power Amplifier”, Journal of the Audio Engineering Society, Vol. 39, No. 6, 1991.).

It should be noted that, although the coefficients of the delta-sigma modulator are fixed in the above-described prior art, there is a modulator that selects the filter coefficients in accordance with an input signal level with the purpose of making the amplitude frequency properties of the quantization noise coincide with the auditory sensitivity properties of humans, and the configuration thereof is shown in FIG. 2 (e.g., see JP-A-7-15281, page 3 and FIG. 1).

In the prior art shown in FIG. 2, the level of an m-bit input signal is detected by a level detection unit 103, and the result of determination by a level determination unit 104 is input to a filter coefficient storage memory 105. Filter coefficients that make the amplitude frequency properties of quantization noise coincide with auditory sensitivity properties changing in accordance with the level of the m-bit input signal is stored in advance in the filter coefficient storage memory 105. Properties of a variable filter 106 are determined by the filter coefficients selected in accordance with the level determined by the level determination unit 104, and a difference between the output of an adder 101 and an output signal of a quantizer 107 is input to the variable filter 106 and added to the m-bit input signal.

However, there are the following problems in the conventional delta-sigma modulator. In order to raise the S/N ratio, it must be ensured that the amount of noise shaping is increased using a (high-order) delta-sigma modulator of a high-order circuit configuration. However, in a high-order delta-sigma modulator, the system becomes unstable when the amplitude of the input signal becomes large, and sometimes oscillation occurs. As a result, a balance between a high S/N ratio and stabilization of the system cannot be achieved.

Thus, in a case where the filter coefficients are fixed, the maximum amplitude of the input signal must be restricted when a high-order delta-sigma modulator is used in order to raise the S/N ratio. As a result, it becomes necessary to raise the voltage at the power switching stage in order to obtain a predetermined output, which is a disadvantage in terms of performance and costs. Conversely, because a low-order delta-sigma modulator must be used in order to allow an input signal of a large amplitude, it is difficult to raise the S/N ratio.

Also, in the conventional example shown in FIG. 2, the delta-sigma modulator is configured so that an average value of the absolute value of the amplitude of the input signal in a past predetermined period of time is detected, the level of this value is determined, and switching is conducted by the level. However, there are problems in that, because that which is detected is a past level, there is a great potential for the level to have already changed before the filter coefficients are switched, and it is difficult to achieve a balance between a high S/N ratio and stability of the system. These problems can be listed as examples among the problems that the present invention attempts to solve.

### SUMMARY OF THE INVENTION

According to a first aspect of the invention, a delta-sigma modulator shifts quantization noise of a digital audio signal to a high-frequency band to reduce noise of the band of the digital audio signal. The delta-sigma modulator includes a quantization bit rate detecting unit configured to detect a quantization bit rate of the digital audio signal, a volume setting value detecting unit configured to detect a volume setting value of the digital audio signal, a filtering unit configured to have plural sets of filter coefficients having different shaping properties and allow the quantization noise to pass, and a filter coefficient switching unit configured to switch the filter coefficients of the filtering unit in accordance with the detection result of the quantization bit rate detecting unit and the detection result of the volume setting value detecting unit.

According to a second aspect of the invention, a method of switching a delta-sigma modulator, includes detecting a quantization bit rate of a digital audio signal, detecting a volume setting value of the digital audio signal, and switching filter coefficients in accordance with the quantization bit rate and the volume setting value.

According to a third aspect of the invention, a digital amplifier includes the delta-sigma modulator as described above.

### BRIEF DESCRIPTION OF THE DRAWINGS

FIG. 1 is a block diagram showing the configuration of a conventional quintic delta-sigma modulator.

FIG. 2 is a block diagram showing a conventional delta-sigma modulator described in Patent Document 1.

FIG. 3 is a functional block diagram showing a digital amplifier according to an embodiment of the invention.

FIG. 4 is a block diagram showing an example of a delta-sigma modulation circuit configuring a delta-sigma modulator according to the embodiment of the invention.

FIG. 5 is a chart showing noise shaping properties of the delta-sigma modulation circuit of FIG. 4.

FIG. 6 is a block diagram showing the configuration of the delta-sigma modulator according to the embodiment of the invention.

FIG. 7 is a graph showing a threshold and a filter switching point in time when a volume setting rises.

FIG. 8 is a graph showing a threshold and a filter switching point in time when the volume setting falls.

FIG. 9 is a block diagram showing another example of a delta-sigma modulation circuit configuring the delta-sigma modulator according to the embodiment of the invention.

FIG. 10 is a block diagram showing yet another example of a delta-sigma modulation circuit configuring the delta-sigma modulator according to the embodiment of the invention.

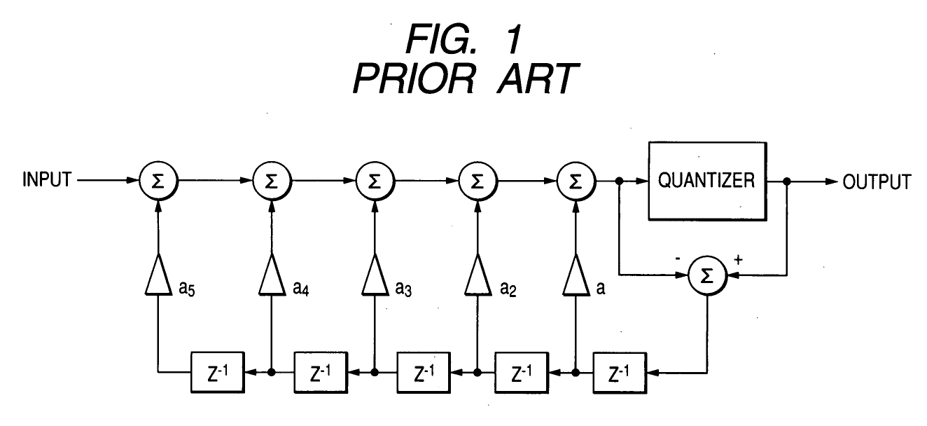

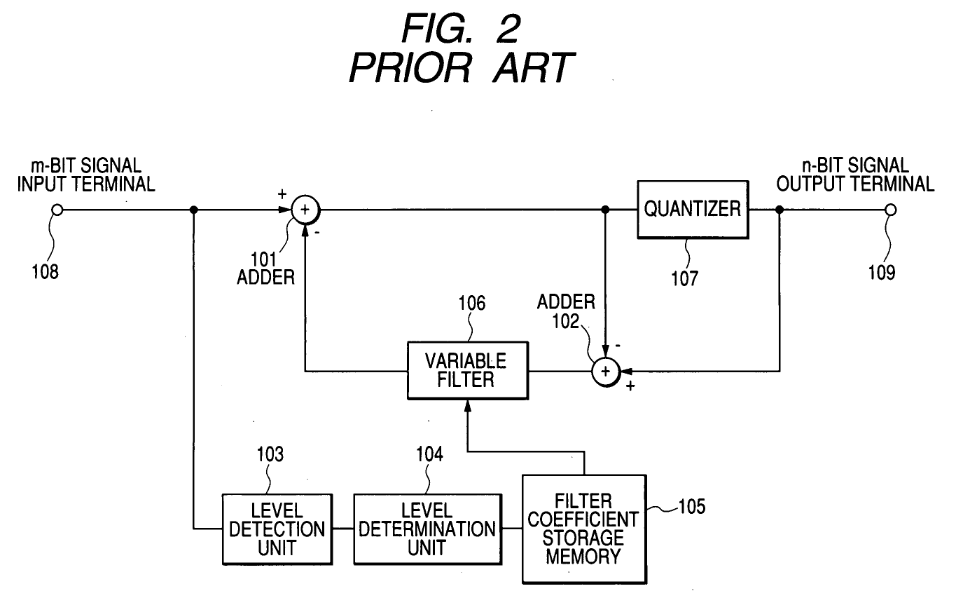

### DETAILED DESCRIPTION OF THE PREFERRED EMBODIMENTS

An embodiment according to the invention will be described in detail below on the basis of the drawings.

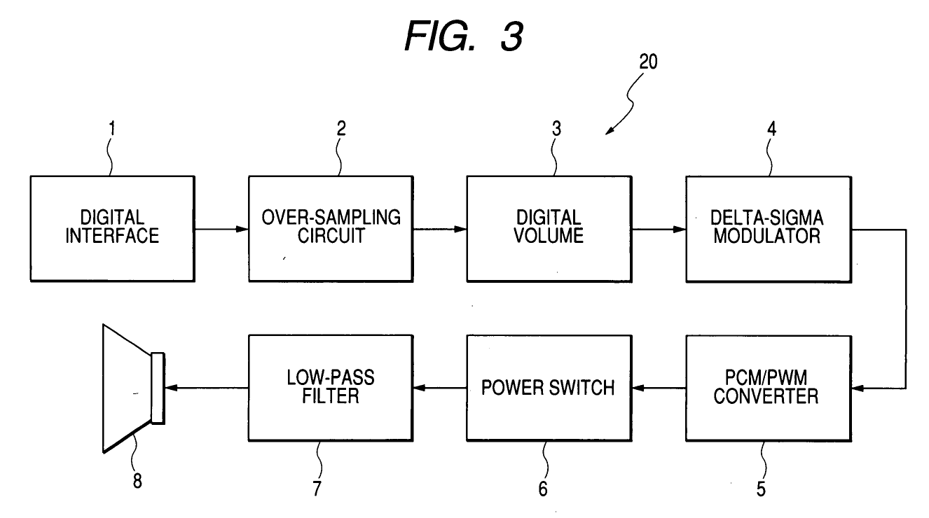

FIG. 3 is a functional block diagram of a digital amplifier using a delta-sigma modulator according to the embodiment of the invention.

In FIG. 3, a digital amplifier 20 using the delta-sigma modulator according to the embodiment of the invention includes: a digital interface 1 that acquires an input signal from a digital source such as a CD (Compact Disc) or a DVD (Digital Versatile Disc); an over-sampling circuit 2 that over-samples the input signal acquired from the digital source via the digital interface 1; a digital volume 3 that adjusts gain with respect to the input signal whose sampling frequency has been raised; a delta-sigma modulator 4 that reduces a quantization bit rate with respect to the gain-adjusted input signal; a PCM (Pulse Code Modulation)/PWM (Pulse Width Modulation) convertor 5 that converts a pulse code modulation signal obtained by the delta-sigma modulator 4 into a pulse width modulation signal; a power switch 6 that switches an unillustrated power source using the period of the pulse width modulation signal, amplifies the amplitude of the pulse width modulation signal and generates a current applied to a speaker 8; and a low-pass filter 7 that removes the high-band component included in the generated current.

Next, the delta-sigma modulator according to the embodiment of the invention will be described.

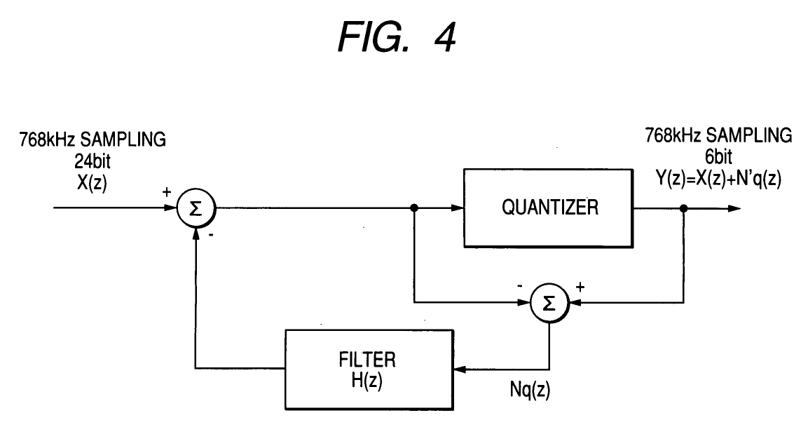

First, an example of a delta-sigma modulation circuit making up the delta-sigma modulator 4 according to the embodiment of the invention is shown in FIG. 4, and the basic configuration and operation thereof will be described.

As shown in FIG. 4, the delta-sigma modulation circuit includes an adder Σ, a filter and a quantizer. In FIG. 4, quantization noise Nq(z) is fed back to an input side via the filter H(z). As a result, the spectrum of the quantization noise is transformed by the following equation.

Nq′(z)=(1−H(z))Nq(z) (1)

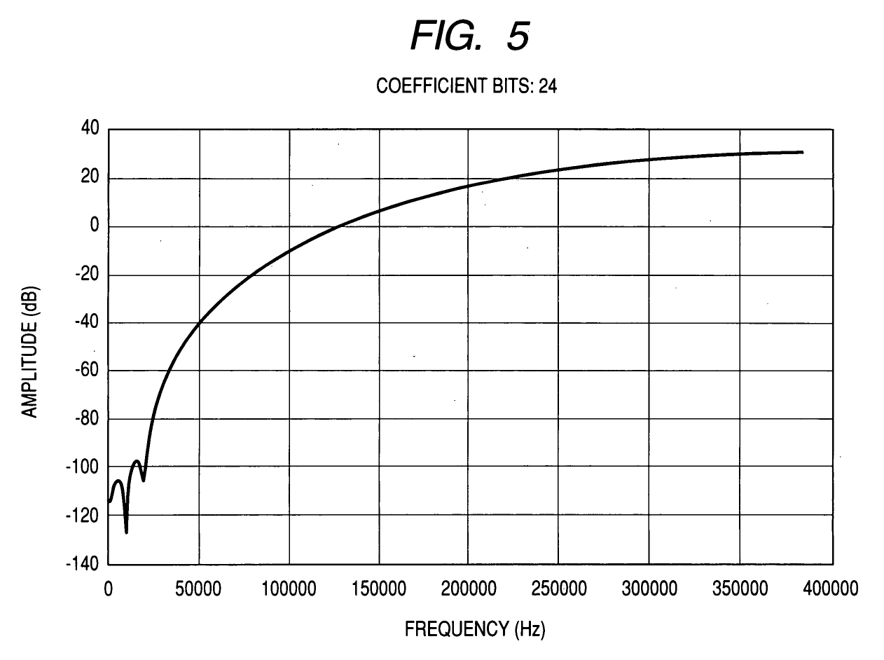

Here, for example, when a 24-bit signal of 768 kHz is input, a 6-bit output signal Y(z) is output. Ordinarily, in the digital amplifier, the filter H(z) is appropriately designed and, as shown in the noise shaping property graph shown in FIG. 5, the quantization noise is shifted to a high-frequency band, whereby the noise of the audio band is reduced and the S/N ratio is secured.

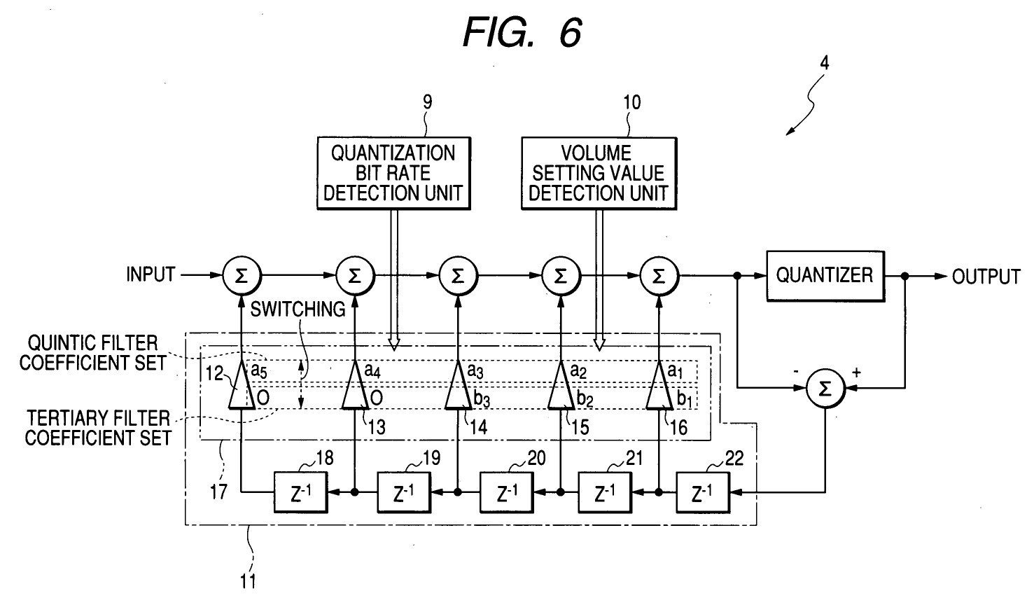

The delta-sigma modulator 4 according to the embodiment of the invention is configured as shown in FIG. 6 using a quintic delta-sigma modulation circuit (e.g., the circuit shown in FIG. 4).

As shown in FIG. 6, the delta-sigma modulator 4 includes a quantization bit rate detection unit 9 that detects the quantization bit rate of a digital audio signal that is the input source; a volume setting value detection unit 10 that detects a volume setting value of the digital audio signal; a filter 11 that includes plural sets of filter coefficients having different shaping properties and allows the quantization noise to pass; and a filter coefficient switcher 17 that switches the filter coefficients of gain adjustors 12 to 16 of the filter 11 in accordance with the bit rate and the volume setting value of the digital audio signal.

In this manner, because the delta-sigma modulator 4 according to the embodiment of the invention includes a quintic delta-sigma modulation circuit, the number of coefficients for each of delta-sigma conversion circuits is five. Additionally, the delta-sigma modulator 4 is characterized in that it plurally has filter coefficients where the five coefficients are used as one set.

That is, as shown in FIG. 6, the delta-sigma modulator 4 has two sets of filter coefficients: quintic (high-order) filter coefficients (a1, a2, a3, a4, a5) and tertiary (low-order) filter coefficients (b1, b2, b3, 0, 0). In this manner, a tertiary (low-order) delta-sigma converter is realized by the tertiary (low-order) filter coefficients having two 0 coefficients.

As a specific example of the quintic and tertiary filter coefficients used here, an example such as the following numerical values can be given.

Quintic filter coefficients: (−5, 10, −10, 5, −1)

Tertiary filter coefficients: (−3, 3, −1, 0, 0) The filter coefficient switcher 17 always switches the filter coefficients to the tertiary filter coefficient set (b1, b2, b3, 0, 0) in the case of a source having a low quantization bit rate such as a CD, and in principle switches the filter coefficients to the quintic filter coefficients (a1, a2, a3, a4, a5) in the case of a source having a high quantization bit rate such as a DVD. However, the tertiary filter coefficients are used in a case where the volume setting value is set higher than a threshold value, which is lower than the maximum value thereof by a predetermined value, even in the case of a source with a high quantization bit rate.

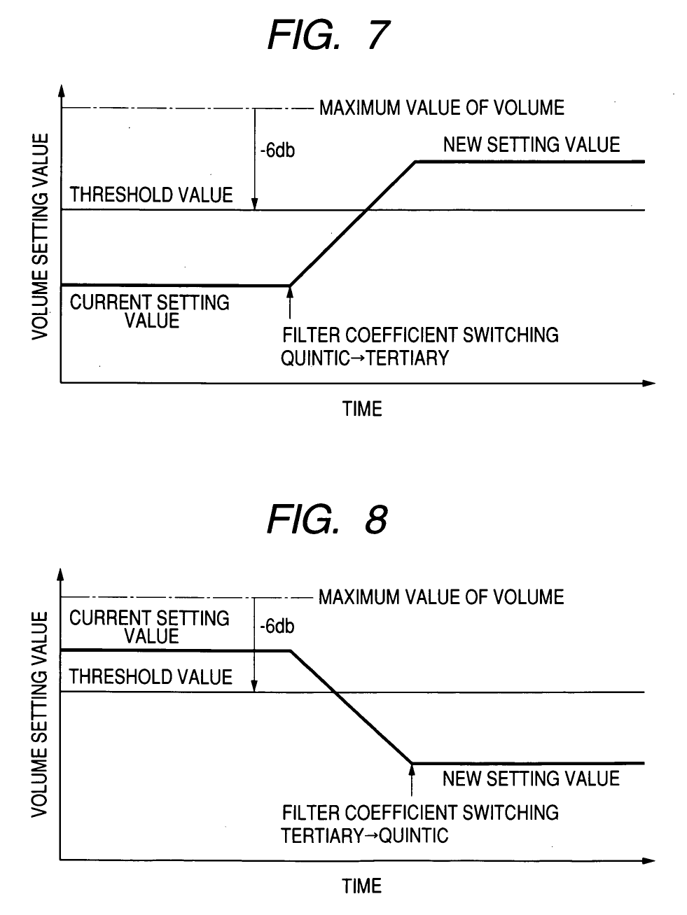

At the time that the volume setting value rises, as in FIG. 7 that shows the threshold value and the point in time where the filter coefficients are switched, the filter coefficients are switched from quintic (high-order) to tertiary (low-order) when the volume setting value that had been set lower than the predetermined threshold value is changed to a value higher than the threshold value.

Conversely, at the time that the volume setting value falls, as in FIG. 8 that shows the threshold value and the point in time where the filter coefficients are switched, the filter coefficients are switched from tertiary (low-order) to quintic (high-order) when the volume setting value that had been set higher than the predetermined threshold is changed to a value lower than the threshold.

Assuming, for example, that the maximum value of the volume setting is 0 dB, the threshold shown in FIGS. 7 and 8 is preferably about −6 dB. The reason for this is because oscillation occurs when the input amplitude is not held to about 60% or less of the maximum value of the volume setting value with the quintic filter coefficients.

Also, when the filter coefficients are switched from tertiary to quintic, the filter coefficient switcher 17 resets memories 18 to 22 storing the quantization noise to zero.

The reason for this is to prevent the quantization noise frombeing excessively fed back when the filter coefficients are switched from the tertiary filter coefficient set to the quintic filter coefficient set, because the numerical values of the quintic filter coefficients are larger than those of the tertiary filter coefficients, as in the specific example of the numerical values mentioned above.

It should be noted that it is not necessary to reset the memories when the filter coefficients are switched from quintic to tertiary. However, because a control program is required in order to ensure that the memories are not reset, here, the memories may be reset in order to simplify the overall control program.

Moreover, when the gain rises from a current volume setting value shown in FIG. 7 to a new volume setting value, the filter coefficients are switched from quintic (high-order) to tertiary (low-order) near the point in time when the rising starts. When the gain falls from the current volume setting shown in FIG. 8 to a new volume setting, the filter coefficients are switched from tertiary (low-order) to quintic (high-order) near the point in time when the falling ends.

By switching the filter coefficients near the point in time when the rising starts and near the point in time when the falling ends, the high-order filter coefficient set is always used with a volume setting value that is lower than the threshold (predetermined value). Thus, the system can be prevented from becoming unstable.

Next, the operation of the digital amplifier according to the present embodiment will be described.

After the over-sampling circuit 2 has raised the sampling frequency of the input signal from a digital source such as a CD or a DVD acquired via the digital interface 1, the digital volume 3 adjusts the gain.

Then, the delta-sigma modulator 4 reduces the quantization bit rate of the gain-adjusted input signal. After the pulse code modulation signal obtained by the delta-sigma modulator 4 has been converted into the pulse width modulation signal by the PCM/PWM converter 5, the unillustrated power source is switched by the power switch 6 using the period of the pulse width modulation signal, the amplitude of the pulse width modulation signal is amplified, and the current applied to the speaker 8 is generated. After the high-frequency component of the generated current has been removed by the low-pass filter 7, the current is applied to the speaker 8.

Then, in the delta-sigma modulator 4, the filter coefficients are switched to the tertiary filter coefficient set in the case of a source whose input signal has a low quantization bit rate and switched to the quintic filter coefficient set in the case of a source having a high quantization bit rate.

In the case of a source having a high quantization bit rate, the filter coefficients are switched from quintic to tertiary when the volume setting value of the digital volume 3 has been changed to a value of about 50% or more of the maximum value thereof.

Also, the memories storing the quantization noise are reset to zero when the filter coefficients are switched from tertiary to quintic.

In this manner, the delta-sigma modulator 4 detects the quantization bit rate of the input signal (quantization bit rate detection step), switches the filter coefficients to the tertiary filter coefficient set in the case of a source having a low quantization bit rate, and switches the filter coefficients to the quintic filter coefficient set in the case of a source having a high quantization bit rate (filter coefficient switching step). Thus, with respect to a source having a low quantization bit rate, the S/N ratio that the source has can be secured even with a tertiary delta-sigma modulator, and the system does not become unstable even if the amplitude of the input signal becomes large. Additionally, with respect to a source having a high quantization rate, the S/N ratio can be set high by the delta-sigma modulator 4 operating as a quintic delta-sigma modulator.

Also, even in the case of a source having a high quantization bit rate, the delta-sigma modulator 4 detects the volume setting value (volume setting detecting step) and switches the filter coefficients from quintic to tertiary when the value thereof has been changed to a high value of 50% or more of the maximum value (filter coefficient switching step). Thus, because the high-order filter coefficient set is always used with a volume setting that is lower than the threshold, the system can be prevented from becoming unstable.

It should be noted that, because it is rare for the volume value to approach the maximum value, a high S/N ratio can be secured in an ordinary state of use.

Also, the memories storing the quantization noise are reset to zero when the filter coefficients are switched to the high-order coefficients. Thus, the quantization noise can be prevented from being excessively fed back even when the filter coefficients are switched from the tertiary filter coefficient set to the quintic filter coefficient set.

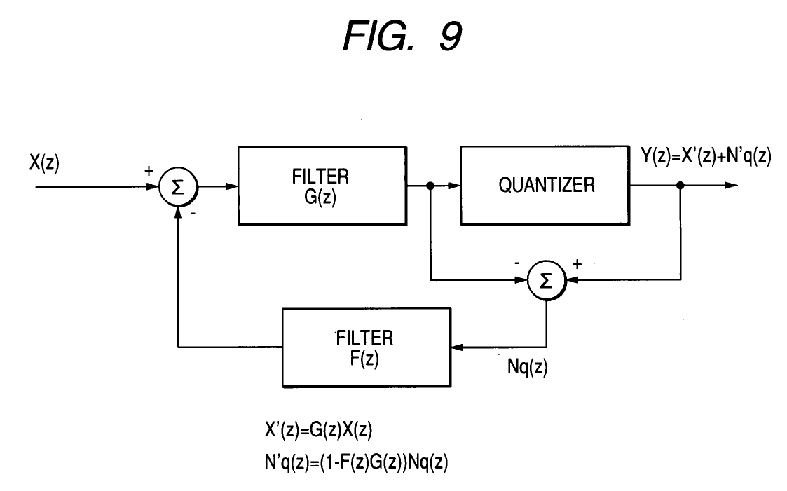

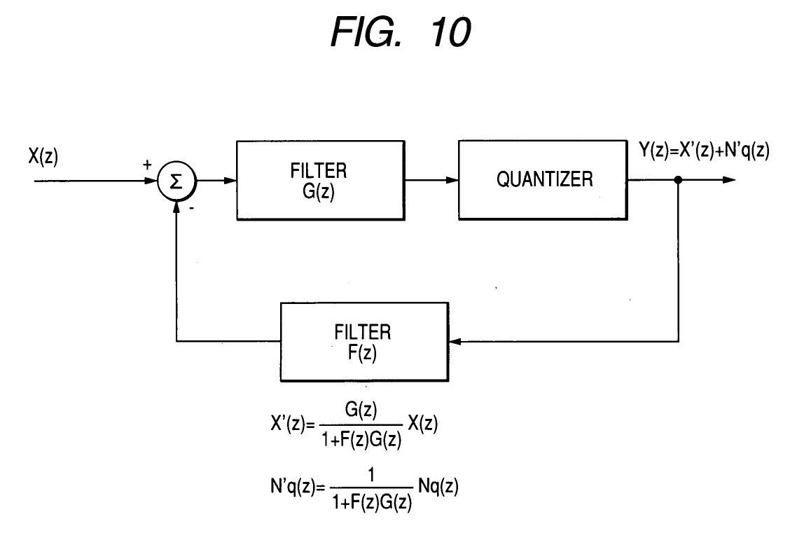

As other examples of the delta-sigma modulation circuit, there are the circuits shown in FIGS. 9 and 10. In the delta-sigma modulation circuits shown in these diagrams, not only the quantization noise but the signal have transfer functions. Thus, although the frequency properties of the signals are not flat, filter coefficient switching can also be applied to delta-sigma modulation circuits of such configurations as in the delta-sigma modulator according to the present embodiment.

As described in detail above, the delta-sigma modulator according to the present embodiment is a delta-sigma modulator that shifts quantization noise of a digital audio signal to a high-frequency band to thereby reduce noise of a band of the digital audio signal. The delta-sigma modulator includes the quantization bit rate detection unit 9 that detects the quantization bit rate of the digital audio signal; the volume setting value detection unit 10 that detects the volume setting value of the digital audio signal; the filter 11 that includes plural sets of filter coefficients having different shaping properties and allows the quantization noise to pass; and the filter coefficient switcher 17 that switches the filter coefficients of the filter 11 in accordance with the detection result of the quantization bit rate detection unit 9 and the detection result of the volume setting value detection unit 10. Thereby, the delta-sigma modulator can switch the filter coefficients of the filter 11 in accordance with the detected value of the quantization bit rate of the input signal and the volume setting value. Thus, the delta-sigma modulator can switch the filter coefficients to the low-order coefficient set in the case of an input signal having a low quantization bit rate and can switch the filter coefficients to the high-order coefficient set in the case of an input signal having a high quantization bit rate. The system does not become unstable even if the amplitude of the input signal becomes large. Also, with respect to an input signal having a high quantization bit rate, the S/N ratio can be set high because the delta-sigma modulator operates as a high-order delta-sigma modulator.

Also, the method of switching the delta-sigma modulator according to the present embodiment includes the quantization bit rate detecting step that detects the quantization bit rate of a digital audio signal; the volume setting detecting step that detects the volume setting value of the digital audio signal; and the filter coefficient switching step that switches the filter coefficients in accordance with the quantization bit rate and the volume setting value. Thus, the filter coefficients can be switched to the low-order coefficient set in the case of an input signal having a low quantization bit rate, and the filter coefficients can be switched to the high-order coefficient set in the case of an input signal having a high quantization bit rate. The system can be prevented from becoming unstable even if the amplitude of the input signal becomes large. Also, with respect to an input signal having a high quantization bit rate, the S/N ratio can be set high.

Also, because the digital amplifier according to the present embodiment includes the delta-sigma modulator of the present embodiment, a balance between a high S/N ratio and stability can be achieved.

What is claimed is:

1. A delta-sigma modulator that shifts quantization noise of a digital audio signal to a high-frequency band to reduce noise of the band of the digital audio signal, the delta-sigma modulator comprising:
a quantization bit rate detecting unit configured to detect a quantization bit rate of the digital audio signal;
a volume setting value detecting unit configured to detect a volume setting value of the digital audio signal;
a filtering unit configured to have plural sets of filter coefficients having different shaping properties and allow the quantization noise to pass; and
a filter coefficient switching unit configured to switch the filter coefficients of the filtering unit in accordance with the detection result of the quantization bit rate detecting unit and the detection result of the volume setting value detecting unit.

2. The delta-sigma modulator according to claim 1, wherein:
the filter coefficients include a first coefficient set and a second coefficient set;
an order of the first coefficient set is lower than that of the second coefficient set; and
the filter coefficient switching unit switches the filter coefficients to the first coefficient set when the quantization bit rate is equal to or less than a predetermined number.

3. The delta-sigma modulator according to claim 1, wherein:
the filter coefficients include a first coefficient set and a second coefficient set;
an order of the first coefficient set is lower than that of the second coefficient set;
the filter coefficient switching unit switches the filter coefficients to the first coefficient set when the quantization bit rate is equal to or greater than a predetermined number and the volume setting value is equal to or greater than a predetermined value; and
the filter coefficient switching unit switches the filter coefficients to the second filter coefficient set when the quantization bit rate is equal to or greater than the predetermined number and the volume setting value is less than the predetermined value.

4. The delta-sigma modulator according to claim 1, wherein:
the filtering unit includes a memory, which stores the quantization noise; and
when the filter coefficient switching unit switches the filter coefficients, contents of the memory are reset.

5. The delta-sigma modulator according to claim 1, wherein:
the filtering unit includes a memory, which stores the quantization noise; and
when the filter coefficient switching unit switches the filter coefficients so that an order thereof becomes larger, contents of the memory are reset.

6. The delta-sigma modulator according to claim 1, wherein:
when the volume setting value is changed and gain rises, the filter coefficient switching unit switches the filter coefficients near the point in time when the rising starts; and
when the volume setting value is changed and gain falls, the filter coefficient switching unit switches the filter coefficients near the point in time when the falling ends.

7. A method of switching a delta-sigma modulator, the method comprising:
detecting a quantization bit rate of a digital audio signal;
detecting a volume setting value of the digital audio signal; and
switching filter coefficients in accordance with the quantization bit rate and the volume setting value.

8. A digital amplifier comprising a delta-sigma modulator that shifts quantization noise of a digital audio signal to a high-frequency band to reduce noise of the band of the digital audio signal, wherein the delta-sigma modulator includes:
a quantization bit rate detecting unit configured to detect a quantization bit rate of the digital audio signal;
a volume setting value detecting unit configured to detect a volume setting value of the digital audio signal;
a filtering unit configured to have plural sets of filter coefficients having different shaping properties and allow the quantization noise to pass; and
a filter coefficient switching unit configured to switch the filter coefficients of the filtering unit in accordance with the detection result of the quantization bit rate detecting unit and the detection result of the volume setting value detecting unit.
